(19) United States
(12) Patent Application Publication
(10) Pub. No.: US 2026/0361327 A1
(43) Pub. Date: Nov. 12, 2026

(54) TRANSMITTER SIGNAL PROCESSOR

(71) Applicant: QINETIQ LIMITED, Farnborough, Hampshire (GB)

(72) Inventor: Malcolm David MACLEOD, Malvern (GB)

(73) Assignee: QINETIQ LIMITED, Farnborough, Hampshire (GB)

(21) Appl. No.: 19/122,873

(22) PCT Filed: Nov. 7, 2023
(86) PCT No.: PCT/EP2023/080925

§ 371 Date: Apr. 21, 2025

(30) Foreign Application Priority Data
Nov. 9, 2022 (GB) 2216710.0

(51) Int. Cl. H04B 1/04

(52) U.S. Cl. CPC H04B 1/0475; H04B 2001/0416; H04B 2001/0433

(57) ABSTRACT

A transmitter signal processor (TSP) for use where multiple independent signals are to be combined, amplified and transmitted whilst maintaining a substantially constant envelope, the processor including a feedback network, whereby an error signal between a sum of the signals and an output of a constant envelope process within the TSP is computed, and, for each input signal this error signal correlated with the input signal to model the effect of the error in a receiver, and to produce a feedback signal by multiplying each error signal by its corresponding input signal, and summing the result for each such input signal, and then subtracting the feedback signal from the sum input. The constant envelope process may be all-digital, such as a normalisation process, and/or may include a part of the analogue transmit chain, such as amplifiers, frequency convertors or filters.

The present invention relates to electronic amplifiers, and more particularly amplifiers used to amplify signals for transmission, where a plurality of signals are required to be transmitted together in an efficient manner.

Often amplifiers are used in applications where the power efficiency of the amplifier is critical. One such application is in satellite systems, where there is often a very limited power budget available to supply all the electronic systems on board. Not only does the power supply (which generally comprises solar panels) cost a lot of money, but as a result of increased size and weight it adversely affects satellite performance in many ways, such as launch rocket size, manoeuvrability, vulnerability to damage etc. Furthermore, dissipating waste heat which results from amplifier inefficiency is a serious challenge for a satellite in space, again resulting in extra cost and weight.

Global navigation satellite systems (GNSSs), such as the US Global Positioning System (GPS), the European Galileo system, or the Chinese Beidou systems each comprise of a number of satellites (typically 15-30) in orbit around the earth. The trend in modern GNSS is to transmit a greater number of signals from one satellite. These signals may support multiple different GNSS “services” with, for the purposes of this application, each service being associated with one or more signals.

Each of the individual signals may be a constant envelope signal, but it is very difficult to maintain a constant envelope when the signals are combined together, particularly where the combined signal is subsequently filtered. The result can be the production of undesired intermodulation signals which are wasteful of energy, compared to the ideal solution of producing a combined signal of constant envelope that can then be fed into a constant envelope amplifier.

One way of processing the multiple signals in a satellite signal transmitter is to use a separate transmit amplifier for each one, with each signal being a constant envelope signal, for maximum efficiency, and then combining these amplified signals before sending them to a transmit antenna. This therefore provides Constant Envelope High Power Amplification. However, the step of combining the high power signals for transmission through one antenna is an engineering challenge, and overall this solution has size, cost and weight penalties. Note that a constant envelope signal is one where the amplitude of the signal is not modulated. It may synonymously be known as a constant amplitude signal.

Solutions to these problems have been sought which take non-constant-amplitude multiplexes of signals and modify them before they are passed through the amplifier, with the aim of maximising the fraction of output power which carries the desired signals, which correspondingly means minimising the fraction of output power which goes into useless erroneous signals known as intermodulation signals.

An alternative approach is to use a single, power-efficient, constant envelope amplifier. A known technique that works on this basis is called Phase Optimised Constant Envelope Transmission (POCET), and is described in U.S. Pat. No. 8,774,315. It works by using pre-computed tables of composite signal phase values, with a value from the table being chosen through an optimisation process that minimises or reduces envelope variation for a phase modulated carrier subject to intra-signal constraints for the multiple input signals.

International patent application WO01/058026 discloses an approach whereby signals from individual sources in a transmission system are combined and amplified in a power amplifier, whilst simultaneously the signals are combined and subtracted from a part of the amplified combined signal to provide an error signal that is a measure of the distortion produced by the amplification process. The error signal is then adjusted in phase and amplitude before being combined with the power-amplified signal to compensate for the distortion, in a feed-forward system.

It is an object of the present invention to provide an alternative approach to the efficient generation of transmission signals.

According to a first aspect of the present invention there is provided a transmitter having a transmitter signal processor (TSP) for processing a plurality of signals for transmission to produce an output signal of constant envelope, the transmitter signal processor having a sum input comprising a sum of the plurality of signals for transmission, and further inputs comprising of each signal for transmission, and an output, the TSP being arranged to compute an error signal between the sum input and the output of the TSP, and for each input signal, to model the effect of the error in a receiver by correlating the error signal with the input signal and to use the sum of the effects for each input signal to generate a correction signal that is fed back, in a feedback loop, to an input of the TSP.

Embodiments of the invention thus employ a feedback approach to ameliorating distortion caused by the amplification of multiple signals where a constant envelope is desired.

Some embodiments of the invention may comprise a transmitter wherein the feedback loop generates a combined feedback signal that is subtracted from the sum input to produce a “constant envelope input signal”, the feedback loop comprising, for each input signal,
a) a correlator arranged to generate a correlation between (i) said input signal and (ii) an error signal comprising a measurement of a difference between the sum input and an output of a constant envelope process or within the TSP; and
b) a multiplier arranged to multiply the result of the correlation at step (a) with said input signal, to produce a multiplier output;
the signal processor being further arranged to sum the output of the multiplier at step (b) for each input signal to produce a combined feedback signal and to feed back the combined feedback signal to the sum input of the signal processor
wherein the constant envelope process comprises either of a normalisation function, or an analogue signal processing chain or a digital model thereof.

Embodiments may provide a transmitter that is able to process multiple (e.g. 2, 3, 4, 5 or more inputs) digital input signals for transmission, generating an output signal for transmission that has a substantially constant envelope.

It will be appreciated by the normally skilled person that the correlator, at (a), is carrying out a similar process to that which would occur in a receiver of the signal transmitted by the transmitter. This is evident because the sum input signal of (a) is of similar form to that of a reference signal used in a correlator in a well-designed receiver, and the transmitted signal is (in part) that received at the receiver. The output of the correlator therefore gives a representation as to the effects of distortion caused by the constant envelope process, as it would be seen at a receiver. This correlator output is, at (b), multiplied by the input signal to form (along with contributions from similar signals produced for each of the other input signals) the combined feedback signal that is subtracted from the sum input signal to the TSP. Thus, in effect, the distortion error caused by the constant envelope process is continuously subtracted from the input, which at least partially counters said distortion.

The output signal may in some embodiments be a digital signal that is then converted to an analogue signal in a digital to analogue converter (DAC), and amplified and, if necessary, up-converted in frequency before being transmitted.

Other embodiments may include outputs of a DAC and an amplifier and/or up-converter as a part of a feedback loop of the transmitter signal processor (TSP), which enables the TSP to take into account distortions added by these components, and so lead to an improved, more constant envelope, signal that is transmitted by the transmitter. Alternatively, a digital model of one or more components, such as a DAC, and up-converter and/or an amplifier may be used in the feedback loop of the TSP, rather than the corresponding analogue components. Accordingly, in some embodiments of the invention, the constant envelope process comprises an analogue signal processing chain having at least one of an amplifier or a frequency up-converter, or comprising a digital model thereof.

In those embodiments that incorporate analogue elements such as a frequency up-converter and/or an amplifier, the feedback loop further comprises a digital to analogue converter, along with a frequency down-converter where an up-converter is present in the constant envelope process. This enables an analogue signal, which may be at a different frequency to that of the different signals provided to the input of the TSP, to be brought to the same frequency as those input signals and be more conveniently processed in the feedback loop.

In some embodiments the processing within the TSP occurs entirely within the digital domain, and the constant envelope process may comprise a normaliser arranged to compute an output o(t)=βw(t)/|w(t)|, where β is the desired constant amplitude and w(t) is the sum input, or a scaled version thereof.

Advantageously, in some embodiments the correlator comprises a multiplier arranged to multiply the complex conjugate of signal (i) with signal (ii), and to accumulate the result in an accumulator.

Advantageously, a high pass filter may be included in the correlator between the multiplier and the accumulator, to remove a low frequency component from an output of the multiplier. This prevents any such low frequency components (including DC, or near-DC signals) from accumulating and causing errors.

Advantageously, the transmitter may further include scaling means for scaling the input signals prior to their being summed at the sum input. The scaling means may comprise one or more multipliers. The multiplier(s) may preferably be implemented digitally. The multipliers may be arranged to scale each input signal independently. The scaling provided by the scaling means may be adjustable in operation of the TSP. The adjustment to the scaling may be determined by measurement of a DC component removed by the high pass filter.

According to a second aspect of the invention there is provided a method of combining a plurality of digital input signals for transmission by a transmitter, the method acting to produce an output signal of constant envelope, and the transmitter having a transmitter signal processor (TSP) configured to sum the digital inputs to produce a sum input, and to compute an error signal between the sum input and the output of the TSP, and to, for each digital input signal, model the effect of the error as would occur in a receiver by correlating the error signal with the digital input signal, and to use the sum of the modelled effects for each digital input signal to generate a correction signal, and to feed back the correction signal, in a feedback loop, and to subtract the feedback signal from the sum input of the TSP.

Advantageously, in some embodiments, the method may further comprise a method wherein the sum signal is fed into a constant envelope processor in the TSP that comprises at least a normalisation function or an analogue signal processing chain, or a digital model thereof, and which produces an output;
wherein the feedback signal is produced by the following steps:
i) measuring an instantaneous error signal by taking the difference between the sum input and the output;
ii) for each input signal, modelling the effect of the instantaneous error signal, by correlating the instantaneous error signal with the input signal, and multiplying the output of the correlation with the input signal;
iii) summing the results of the multiplication in step (ii) produced for each input signal, with the result of this summation comprising the feedback signal;
wherein the constant envelope process comprises either of a normalisation function, or an analogue signal processing chain.

Advantageously, the constant envelope processor may be arranged to normalise, using a normaliser, the constant envelope input signal.

In some embodiments the constant envelope process comprises a digital to analogue converter, and at least one of a frequency upconverter and an RF amplifier, and wherein the output for the purposes of (i) of this second aspect is derived from a downconverted and digitised version of an output from the RF amplifier and/or upconverter.

In some embodiments the constant envelope process comprises a digital model of at least a part of an analogue processing chain, including at least a power amplifier, of a transmitter in which the method is implemented. Advantageously, the digital model may have inputs from the analogue processing chain, and may be adapted to change parameters of the digital model based upon these inputs.

Embodiments of the invention will now be described in more detail, by way of example only, and with reference to the following Figures, of which:

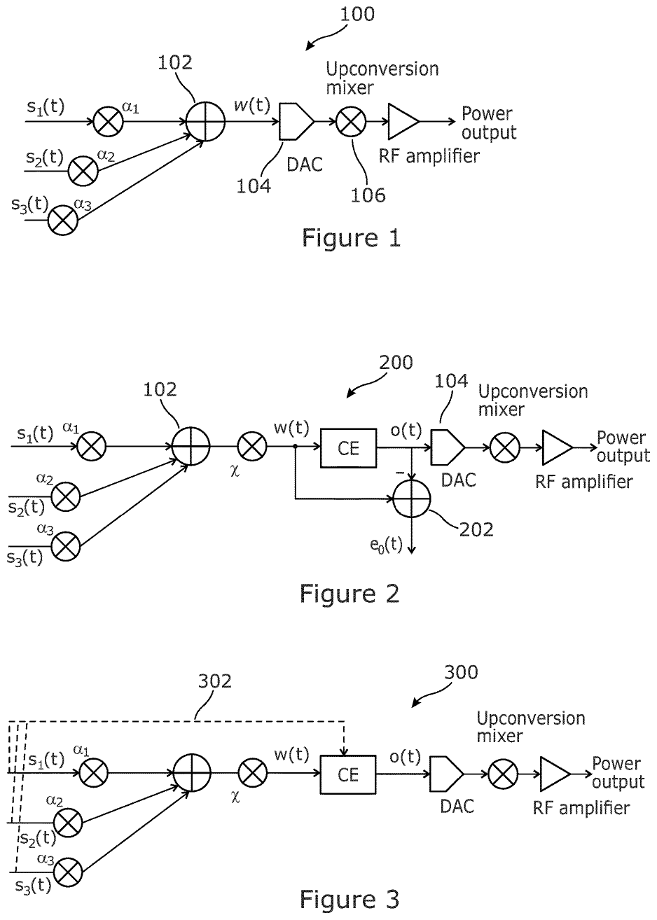

FIG. 1 shows a high level representation of a transmitter arranged to transmit multiple independent signals through a common up-conversion and amplification process;

FIG. 2 shows a high level representation of a prior art process for achieving a constant envelope output signal;

FIG. 3 shows a high level representation of an improved prior art process for achieving a constant envelope output signal;

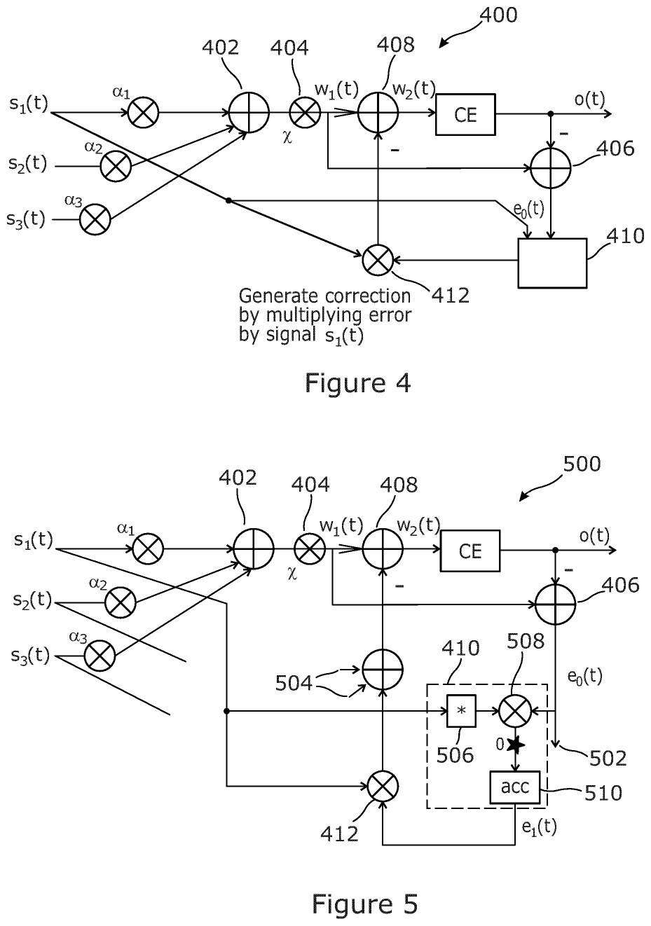

FIG. 4 shows a high level architecture of an embodiment of the present invention;

FIG. 5 shows a more detailed architecture of an embodiment of the present invention, operable completely in the digital domain;

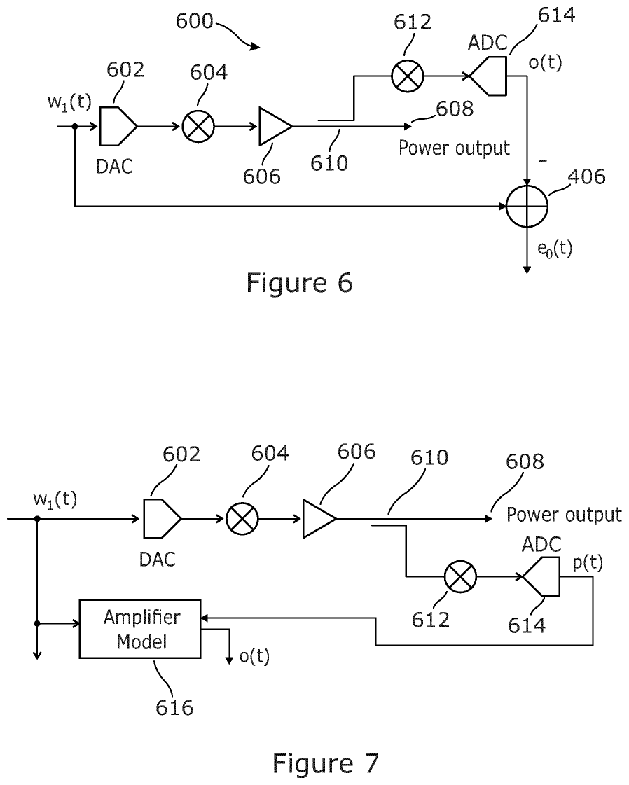

FIG. 6 shows partial detail of an alternative embodiment of the present invention, where some elements are operable in the analogue domain; and

FIG. 7 shows partial detail of an alternative embodiment of the present invention, where a digital model of analogue components are used.

FIG. 1 shows a simple transmitter architecture 100, where three independent digital input signals s₁(t)-s₃(t) are scaled in multipliers α₁-α₃ before being summed in summer 102 to produce a combined digital signal w(t). This is then converted to analogue form in digital-to-analogue converter (DAC) 104 before being up-converted by mixing with a local oscillator signal (not shown) in mixer 106, and amplified in amplifier 108. It is then fed to an antenna (not shown) for transmission. In general, there may of course be a different number of input signals sᵢ(t) in a given system. A typical application may comprise a GNSS satellite, and the signals sᵢ(t) may comprise different navigation signals, such as an open navigation signal, along with commercial, public regulated service, and safety of life navigation signals, and pilot signals, which may be at different frequencies, bandwidths or phases to each other.

The signal w(t) is the wanted signal for transmission. However, due to the independence of the signals sᵢ(t) the envelope of w(t) can vary, for example as each signal itself varies in amplitude or phase. The variation of the envelope of w(t) leads to inefficiencies, particularly within the RF amplifier, such as the generation of intermodulation signals as mentioned earlier which, when the amplifier is in a challenging environment such as a satellite, can be costly in terms of additional cooling requirements, or excess power input required to achieve a given performance.

FIG. 2 shows a simple prior art technique 200 for generating a constant envelope signal. It is similar to the architecture of FIG. 1, but with the addition of new blocks in the signal path between the summer 102 and the DAC 104. The new blocks comprise a scaling means x (which can be ignored for the purposes of this paragraph), and the “constant envelope” (CE) block, which takes signal w(t) and produces an output o(t)=βw(t)/|w(t)|) of constant (or more constant than its input) envelope. Thus, it acts to normalise the input signal to an amplitude β, All known techniques for producing a constant envelope distort the output signal to a degree, but this simple approach performs badly compared to other techniques, including embodiments of the current invention.

Measurement of the error produced by the approach can be done by subtraction, in subtractor 202 of the output signal of the CE block from the input signal, to produce instantaneous error signal e₀(t). When implementing a technique as shown in FIG. 2, the power of the error e₀(t) would generally be minimised by design by adjusting the scaling factor χ, such that the mean squared value of w(t) equals the mean squared value of o(t), which is β².

χ²{E[|α₁|²|s₁(t)|²]+E[|α₂|²|s₂(t)|²+E[|α₃|²|s₃(t)|²]]}=β²

Alternatively, and equivalently, the three scale factors α₁, α₂ and α₃ could be adjusted by a common scale factor of χ. Assuming the scale factors are fixed, this is all set up once only. It should be noted that known implementations of any system of the type shown in FIG. 2 do not actually use the error signal e₀(t) in any real-time correction process—it is illustrated here simply to show where the error would be measured.

This simple prior art approach has two limitations:
There is no control over the power density spectrum of noise added by the action of the CE block; and
There is no control over the actual signal power which is seen by receivers matched to the individual signals

An improved prior art technique 300 is shown in FIG. 3. This is the technique used by prior art document U.S. Pat. No. 8,774,315 which, as stated above, uses precomputed tables to generate an output signal, based upon the individual input signals as presented to the CE component by the dotted line connections 302. These tables take possible combinations of input signals, such as a discrete number of different phases for each (for phase modulated signals), and precompute an ideal output signal for each possible input combination.

FIG. 4 shows at a top level a system 400 according to an embodiment of the present invention. The basic principle of this embodiment, and all embodiments of the invention, is the use of negative feedback of the error signal e₀(t) to correct for errors introduced by the constant envelope process. The error signal e₀(t) is equivalent to the error signal as shown in FIG. 2, but in this embodiment the error signal is used as explained below, to produce the feedback signal.

Signals s₁(t)-s₃(t) are the input signals which need to be combined, and transmitted from a power amplifier. They are scaled by corresponding scaling factors α₁-α₃ and summed in summer 402, providing a summation output. A further combined scaling may performed on the summation output at 404, or alternatively this scaling may be done by incorporating an appropriate common factor to the individual scaling factors α₁-α₃. The output of this is signal W1(t), which provides a first input to a summation node 406, to calculate the error signal e₀(t). The instantaneous error caused by the conversion to constant envelope (CE) is thus computed.

Signal w₁(t) is also provided to a further summation node 408 in the transmit path at which point a feedback signal is subtracted from it to produce signal w₂(t) This signal then feeds the CE process to produce an output o(t), the CE process in this embodiment being given by o(t)=w₂(t)/|w₂(t)|). The signal o(t) is fed to the summation node 406 as its second input, where it is subtracted from signal w₁(t) to produce e₀(t). Signal o(t) is the constant envelope (digital) signal in this embodiment, which is then converted to an analogue signal and up-converted in frequency and amplified in a power amplifier for transmission, as required.

The feedback signal is produced by taking the error signal and, for each individual input signal sᵢ(t), applying it to a correlator 410 that correlates it with sᵢ(t) to model the effect that the error has on a correlation process that would happen in a receiver, which of course has (in GNSS and other Direct Sequence Spread Spectrum applications), its own locally stored reference copy of signal sᵢ(t). Note that FIG. 4 only shows the correlation and feedback process associated with signal s₁(t), and in practice each signal sᵢ(t) will have its own correlator to provide its own contribution to the feedback signal as is explained later. The correlator output is then multiplied by the signal sᵢ(t) in multiplier 412 to become sᵢ(t)'s contribution to the feedback correction signal. The corrections themselves, due to their being subtracted from signal w₁(t), are distorted by the CE process, but the continuous negative feedback still reduces the cumulative error effect.

FIG. 5 shows in more detail the generation of the feedback signal. The embodiment 500 shown is the same as that of FIG. 4, but with additional elements shown that further clarify the operation of the system. Like reference numbers indicate like functional blocks. As explained earlier, the instantaneous transmitter error e₀(t) is computed, and correlated with each reference signal. This is only shown for signal s₁(t) in the figure; the processing for the other signals uses duplicated blocks. Arrow 502 indicates, for example, a feed to correlators for the other signals sᵢ(t) and arrow 504 indicates the summation of the results of the processing of those signals to create the overall feedback signal. The correlator 410 comprises a conjugator 506 for conjugating the reference signal before it is multiplied by the error signal in multiplier 508. It is then accumulated in accumulator 510 to produce, error signal e₁(t).

An ideal system would add to output signal o(t) a correction to the next sample which, when demodulated by the relevant receiver correlator, would equal the negative of the accumulated error for that signal. This would make the accumulated error on that signal zero after the next sample. This is purpose of multiplier 412 which multiplies the accumulated error from accumulator 510 by the reference signal s₁(t) before summing the result at summer 504 with results from similar processes occurring for other input signals sᵢ(t), and then in adder 406 subtracting the result of the summation from the wanted signal w₁(t), giving a modified wanted signal w₂(t).

The distorting operation of the CE block means that the corrections are also distorted, so the level of correction actually achieved on the next sample is reduced. However, a significant degree of correction does survive the CE block, and modelled performance better than the prior art techniques has been achieved.

A detail to note is that unless the scale factor χ at 404 (or equivalent adjustments made to α₁-α₃) can be simultaneously optimally adjusted, the output amplitude which can actually be achieved for signal component s may not equal (χ αᵢ sᵢ). Therefore the error associated with that signal component can grow without limit. This problem is solved by including a high pass filter at the point indicated by star 0 in the correlator 410. By measuring a DC component removed by the high pass filter, the source signal scale factors (ai) can be adjusted by a slow adaptive algorithm (e.g. an LMS steepest gradient algorithm).

The above embodiments all operate in the digital domain throughout, in that all the processing, and the CE process also, operate in this domain, and provides its output to a DAC which then feeds any required up-conversion and amplification for transmission. Other embodiments may use a CE process that operates at least in part in the analogue domain, with a feedback path coming from an element within the analogue path, typically after an amplification stage. This allows imperfections within the amplifier to be directly taken into account by the processing occurring in the feedback path. These imperfections may include any soft-clipping that occur in the amplifier, and/or any AM to AM, and AM to PM distortion that may occur, where AM is amplitude modulation, and PM is phase modulation.

FIG. 6 shows in top level form part 600 of an embodiment of the invention that has the CE process in analogue form, this comprising part of the transmit chain of a transmitter. Note that the details of the feedback processing are the same as that for the embodiments above, and will not be described in detail further in relation to this figure.

Thus, this figure just shows the analogue equivalent of the (digital) CE block in FIG. 5, along with the error summer 406. The connections to the summer 406 from w₁(t) and o(t), along with the output from summer 406 show the paths to the feedback circuit, this comprising e.g. the feedback circuit as explained in relation to FIG. 4.

Here, the signal w₁(t) is presented to a DAC and the resulting analogue signal is up-converted to the transmit frequency in up-conversion mixer 604, before being passed to an RF amplifier 606 for amplification to a desired transmit output power, to produce an analogue power signal 608 for subsequent transmission via an antenna. This is the step where much of the distortion being corrected for by the method of the invention takes place. A coupler 610 takes a small amount of this transmit energy from the output of the RF amplifier, and brings it back to a baseband signal in downconversion mixer 612, and converts this back to a digital signal in analogue to digital converter 614. It is then fed to the feedback loop to generate the error signal e₀(t) as for previous embodiments.

Unlike the all-digital approach of previous embodiments, this embodiment may introduce a small delay in the signal path. In a GNSS application, where the signals sᵢ(t) comprise a sequence of chips, then provided that any added delay is small compared to one chip duration (which, in the higher GNSS chip rates is about 0.1 μs) this delay can be ignored without any significant problem occurring. However it is not difficult to compensate for such a delay, especially if it is approximately constant. To do this, the delay is measured at the design and test stage of system production. Then that amount of delay is inserted into the digital correction circuits, at the conjugate box 506 in FIG. 5 (albeit that is shown in an all-digital scenario, but the feedback signal generation will be the same in this embodiment as previously stated).

A further potential issue with the embodiment of FIG. 6 is that the RF measurement process, of splitting a signal from an output of the amplifier (in coupler 610), downconverting it in frequency and converting it to digital form may introduce noise. FIG. 7 shows an alternative embodiment that aims to reduce the effects of any such noise that may be present. This embodiment has similarities to that of FIG. 6, in that an output of an analogue transmit chain is used to influence the feedback process. The analogue transmit chain, and the coupler, down-converter and digitiser are similar to that shown in FIG. 6, and hence has the same reference numbers. However, in this embodiment the digitiser 614 output is not directly used, but is instead fed to a digital amplifier model 616. This digital amplifier model is a model of the RF amplifier. It has adjustable parameters that are adapted slowly over a “relatively long” time period, based upon the input from the downconverted and digitised signal from the actual power amplifier, since the characteristics of the RF amplifier will not vary rapidly. This time period may be for example measured in tens or hundreds of milliseconds, or seconds. Their adaptation is controlled by feedback of the error which is the difference between the (downconverted and digitised) amplifier output p(t) and the model output o(t).

The adjustable parameters may take the form of an input-envelope to output-envelope mapping function and an input-envelope to output-phase-error mapping function. Alternatively they may be the parameters of a Volterra function model of the power amplifier. Such models are mentioned in “The Evolution of PA Linearization” by Allen Katz, John Wood, and Daniel Chokola, IEEE Microwave Magazine, February 2016, p. 32.

This embodiment provides the advantage that any noise or error in the coupled output (o(t) is not fed directly into the feedback process described earlier, but is smoothed by the long term adaptation within the model. The model itself, being digital, operates with low output noise.

It will be appreciated by the normally skilled person that the novel techniques described herein are completely different from the existing methods because, whereas they use precomputed tables, the new method uses real-time feedback of errors.

Embodiments of the invention will typically be implemented in software, for example in one or more digital signal processors or microprocessors-the processor or processors being programmable hardware controlled by computer code, or may be operated in firmware/hardware, such as in one or more Application Specific Integrated Circuits (ASIC), or a Field Programmable Gate Arrays (FPGA). Such devices will typically include, or be connected with, a suitable memory and storage, as would be appreciated by a normally skilled person. The invention may extend therefore to a software program arranged to be storable in computer memory and comprising of instructions that cause a processor to implement the various elements described herein. Some embodiments may be implemented in a combination of hardware or software, and the transmitter signal processor may comprise a combination of analogue and digital circuitry arranged to process signals in both the analogue and digital domains. In particular, analogue circuitry forming part of the transmitter signal processor may comprise of one or more amplifiers (including power amplifiers), frequency shifters, filters etc. that form part of a signal processing chain of a signal to be transmitted by an antenna. Embodiments of the invention have utility in many areas of signal transmission, typically in space or airborne application, such as in GNSS satellites, and may also be used more widely for terrestrial radio receivers (where increased power efficiency gives longer battery life and reduced waste heat).

1. A transmitter having a transmitter signal processor (TSP) for processing a plurality of signals for transmission to produce an output signal of constant envelope, the transmitter signal processor having a sum input comprising a sum of the plurality of signals for transmission, and further inputs comprising of each signal for transmission, and an output, the TSP being arranged to compute an error signal between the sum input and the output of the TSP, and for each input signal, to model the effect of the error in a receiver by correlating the error signal with the input signal and to use the sum of the effects for each input signal to generate a correction signal that is fed back, in a feedback loop, to an input of the TSP.

2. A transmitter as claimed in claim 1 wherein the feedback loop generates a combined feedback signal that is subtracted from the sum input to produce a “constant envelope input signal”, the feedback loop comprising, for each input signal,
a) a correlator arranged to generate a correlation between (i) said input signal and (ii) an error signal comprising a measurement of a difference between the sum input and an output of a constant envelope processor within the TSP; and
b) a multiplier arranged to multiply the result of the correlation at step (a) with said input signal, to produce a multiplier output;
the signal processor being further arranged to sum the output of the multiplier at step (b) for each input signal to produce a combined feedback signal and to feed back the combined feedback signal to the sum input of the signal processor;
wherein the constant envelope processor comprises either of a normalisation function, or an analogue signal processing chain or a digital model thereof.

3. A transmitter as claimed in claim 2 wherein, when the constant envelope processor comprises of an analogue signal processing chain, having at least one of an amplifier or a frequency up-converter, or comprises a digital model thereof.

4. A transmitter as claimed in claim 3 wherein the feedback loop further comprises a digital to analogue converter, along with a frequency down-converter where an up-converter is present in the constant envelope process.

5. A transmitter as claimed in claim 1 wherein the processing within the signal processor occurs entirely within the digital domain, and the constant envelope process comprises of a normaliser arranged to compute an output o(t)=βw(t)/|w(t)|, where β is the desired constant amplitude and w(t) is the sum input, or a scaled version thereof.

6. A transmitter as claimed in claim 1 wherein the correlator comprises a multiplier arranged to multiply the complex conjugate of signal (i) with signal (ii), and to accumulate the result in an accumulator.

7. A transmitter as claimed in claim 6 wherein a high pass filter is included in the correlator between the multiplier and the accumulator, to remove a low frequency component from an output of the multiplier.

8. A transmitter as claimed in claim 1 wherein the transmitter further includes scaling means for scaling the input signals prior to their being summed at the sum input.

9. A method of combining a plurality of digital input signals for transmission by a transmitter, the method acting to produce an output signal of constant envelope, and the transmitter having a transmitter signal processor (TSP) configured to sum the digital inputs to produce a sum input, and to compute an error signal between the sum input and the output of the TSP, and to, for each digital input signal, model the effect of the error as would occur in a receiver by correlating the error signal with the digital input signal, and to use the sum of the modelled effects for each digital input signal to generate a correction signal, and to feed back the correction signal, in a feedback loop, and to subtract the feedback signal from the sum input of the TSP.

10. A method as claimed in claim 9 wherein the sum input signal is fed into a constant envelope processor in the TSP that comprises at least a normalisation function or an analogue signal processing chain, or a digital model thereof, and which produces an output;
wherein the feedback signal is produced by the following steps:
i) measuring an instantaneous error signal by taking the difference between the sum input and the output;
ii) for each input signal, modelling the effect of the instantaneous error signal, by correlating the instantaneous error signal with the input signal, and multiplying the output of the correlation with the input signal;
iii) summing the results of the multiplication in step (ii) produced for each input signal, with the result of this summation comprising the feedback signal.

11. The method of claim 10 wherein the constant envelope processor comprises a normaliser for normalising the constant envelope input signal.

12. The method of claim 10 wherein the constant envelope process further comprises a digital to analogue converter, and at least one of a frequency upconverter and an RF amplifier, and wherein the output for the purposes of claim 9(i) is derived from a downconverted and digitised version of an output from the RF amplifier and/or upconverter.

13. The method of claim 10 wherein the constant envelope process further comprises a digital model of at least a part of an analogue processing chain, including at least a power amplifier, of a transmitter in which the method is implement
